(19) United States
(12) Patent Application Publication
(10) Pub. No.: US 2013/0255878 A1
(43) Pub. Date: Oct. 3, 2013

(54) PRINTED CIRCUIT BOARD MANUFACTURING METHOD

(71) Applicant: FUJITSU LIMITED, Kawasaki-shi (JP)

(72) Inventors: Tetsuya TAKAHASHI, Nagano (JP); Yasuo Moriya, Kawasaki (JP); Kimio Nakamura, Suzaka (JP)

(73) Assignee: FUJITSU LIMITED, Kawasaki-shi (JP)

(21) Appl. No.: 13/796,128

(22) Filed: Mar. 12, 2013

(30) Foreign Application Priority Data
Mar. 27, 2012 (JP) 2012-071795

(51) Int. Cl. H05K 3/30

(52) U.S. Cl. CPC H05K 3/305
USPC 156/288

(57) ABSTRACT

A printed circuit board manufacturing method includes: supporting a substrate on a support member; disposing a semiconductor chip on an opposite side of the substrate from the support member and pressing the semiconductor chip against the substrate with a pressing member; and employing as the support member a member formed with a cavity larger than an external profile of the semiconductor chip and formed with a sloping portion towards the center of a bottom face of the cavity.

### CROSS-REFERENCE TO RELATED APPLICATION

This application is based upon and claims the benefit of priority of the prior Japanese Patent Application No. 2012-071795, filed on Mar. 27, 2012, the entire contents of which are incorporated herein by reference.

### FIELD

The embodiments discussed herein are related to a printed circuit board manufacturing method.

### BACKGROUND

It is possible to achieve a thinner board assembly body (board mounted with a semiconductor chip) by making the semiconductor chip for mounting to the board thinner. However, if the semiconductor chip is made thinner then there is a concern regarding warping occurring during bonding to the board due to lower rigidity.

Technology is known in for example multi-layer wiring boards of forming a depleted area where some layer(s) have been removed at positions corresponding to a chip configuration section at the center of a semiconductor component to alleviate differences between deformation behavior of the chip configuration section and deformation behavior of the multi-layer wiring board.

### Related Patent Documents

Japanese Laid-Open Patent Publication No. 2000-216291

### SUMMARY

According to an aspect of the embodiments, a printed circuit board manufacturing method is provided. The printed circuit board manufacturing method includes: supporting a substrate on a support member; disposing a semiconductor chip on an opposite side of the substrate from the support member and pressing the semiconductor chip against the substrate with a pressing member; employing as the support member a member formed with a cavity larger than an external profile of the semiconductor chip to be mounted to the substrate and formed, at at least a portion of a bottom face of the cavity, with a sloping portion towards a center of the cavity, and causing a bump of the semiconductor chip to face towards the sloping portion when the semiconductor chip is pressed towards the substrate; and bonding the semiconductor chip to the substrate with an adhesive interposed between the substrate and the semiconductor chip.

The object and advantages of the invention will be realized and attained by means of the elements and combinations and particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a schematic process diagram illustrating a cross-section of a manufacturing apparatus in a printed circuit board manufacturing method of a first exemplary embodiment.

FIG. 1B is a schematic process diagram illustrating processes subsequent to those of FIG. 1A in a cross-section of a manufacturing apparatus in a printed circuit board manufacturing method of the first exemplary embodiment.

FIG. 1C is a schematic process diagram illustrating processes subsequent to those of FIG. 1B in a cross-section of a manufacturing apparatus in a printed circuit board manufacturing method of the first exemplary embodiment.

FIG. 2A is a plan view illustrating a mounting stage in a manufacturing apparatus of a printed circuit board of the first exemplary embodiment.

FIG. 2B is a cross-section taken along line B-B of FIG. 2A illustrating a mounting stage in a manufacturing apparatus of a printed circuit board of the first exemplary embodiment.

FIG. 3A is a schematic process diagram illustrating a cross-section of a manufacturing apparatus in a printed circuit board manufacturing method of a comparative example.

FIG. 3B is a schematic process diagram illustrating processes subsequent to those of FIG. 3A in a cross-section of a manufacturing apparatus in a printed circuit board manufacturing method of the comparative example.

FIG. 3C is a schematic process diagram illustrating processes subsequent to those of FIG. 3B in a cross-section of a manufacturing apparatus in a printed circuit board manufacturing method of the comparative example.

FIG. 4 is a graph qualitatively illustrating a deformation amount of a semiconductor chip in a printed circuit board manufacturing method of a comparative example.

FIG. 5A is a plan view and a cross-section illustrating a mounting stage applicable to a printed circuit board manufacturing apparatus of the first exemplary embodiment.

FIG. 5B is a plan view and a cross-section illustrating a mounting stage applicable to a printed circuit board manufacturing apparatus of the first exemplary embodiment.

FIG. 5C is a plan view and a cross-section illustrating a mounting stage applicable to a printed circuit board manufacturing apparatus of the first exemplary embodiment.

FIG. 5D is a plan view and a cross-section illustrating a mounting stage applicable to a printed circuit board manufacturing apparatus of the first exemplary embodiment.

FIG. 6A is a schematic process diagram illustrating a cross-section of a manufacturing apparatus in a printed circuit board manufacturing method of a second exemplary embodiment.

FIG. 6B is a schematic process diagram illustrating processes subsequent to those of FIG. 6A in a cross-section of a manufacturing apparatus in a printed circuit board manufacturing method of the second exemplary embodiment.

FIG. 6C is a schematic process diagram illustrating processes subsequent to those of FIG. 6B in a cross-section of a manufacturing apparatus in a printed circuit board manufacturing method of the second exemplary embodiment.

FIG. 7A is a schematic process diagram illustrating a cross-section of a manufacturing apparatus in a printed circuit board manufacturing method of a third exemplary embodiment.

FIG. 7B is a schematic process diagram illustrating processes subsequent to those of FIG. 7A in a cross-section of a manufacturing apparatus in a printed circuit board manufacturing method of the third exemplary embodiment.

FIG. 7C is a schematic process diagram illustrating processes subsequent to those of FIG. 7B in a cross-section of a manufacturing apparatus in a printed circuit board manufacturing method of the third exemplary embodiment.

### DESCRIPTION OF EMBODIMENTS

Detailed explanation follows regarding exemplary embodiments of a printed circuit board manufacturing method (referred to below simply as “manufacturing method”) disclosed in the present application and a portion of a printed circuit board manufacturing apparatus (referred to below simply as “manufacturing apparatus”) applicable to the manufacturing method, with reference to the drawings.

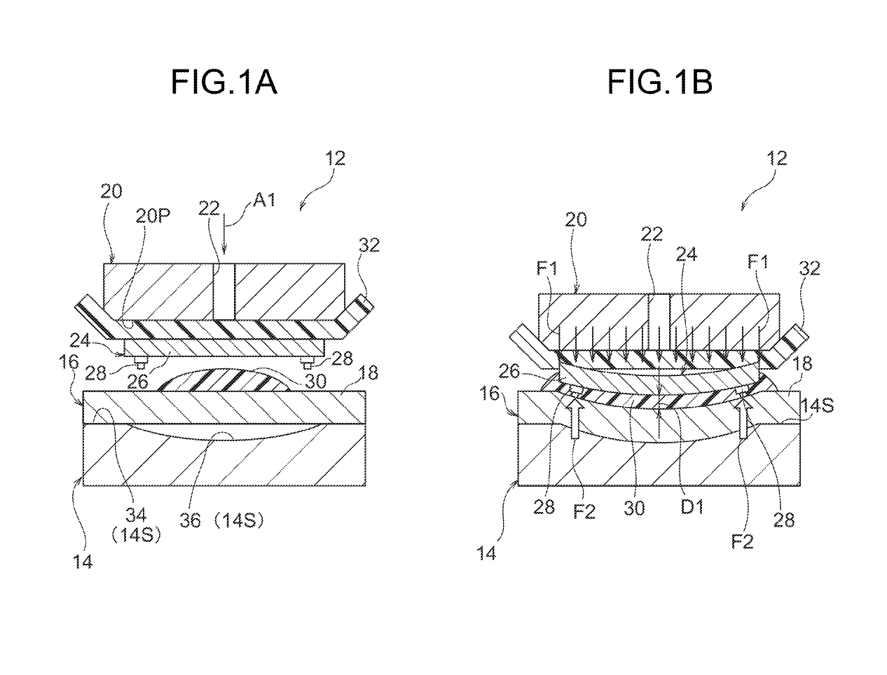

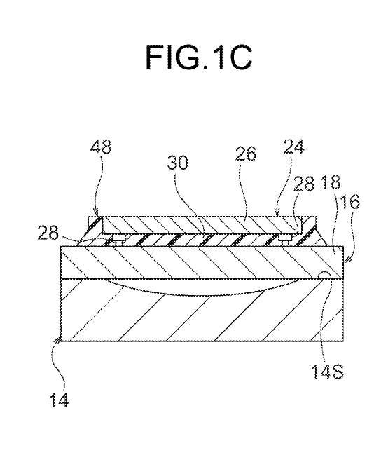

Note that in FIG. 1A and FIG. 1B, a manufacturing apparatus 12 is illustrated in a cross-section taken along a mounting direction of a semiconductor chip 24, described later.

As illustrated in FIG. 1A, the manufacturing apparatus 12 includes a substantially plate shaped mounting stage 14 whose top face configures a support face 14S. A package substrate 16 is supported on the support face 14S. In the first exemplary embodiment, the mounting stage 14 is an example of a support member, the support member being, put simply, any member capable of supporting the package substrate 16. The package substrate 16 is an example of a substrate.

The package substrate 16 includes a base 18 formed in a flat plate shape from a material with a specific insulating ability and rigidity (such as for example an epoxy resin). A desired circuit pattern may be formed on the base 18 with for example copper foil

The manufacturing apparatus 12 includes a press member 20. The press member 20 in the first exemplary embodiment has a flat pressing face 20P that faces towards the support face 14S. A suction hole 22 is provided piercing through the press member 20 in a direction normal to the pressing face 20P. The semiconductor chip 24 can be suctioned towards the pressing face 20P side by applying a negative pressure from a suction apparatus.

The press member 20 is also configured such that at least the pressing face 20P can be heated by a heating mechanism to the melting temperature of an adhesive 30, described later, or higher. It is possible to press the suctioned semiconductor chip 24 forwards against the package substrate 16 on the mounting stage 14 using a driving mechanism.

The semiconductor chip 24 includes a chip body 26 formed in a substantial plate shape and internally formed with a desired circuit in advance. Plural bumps 28 are formed on the chip body 26.

Each of the bumps 28 projects out towards the facing face of the package substrate 16. The leading ends of the bumps 28 make contact with the package substrate 16, thereby mounting the semiconductor chip 24 in a specific position on the package substrate 16, and rendering the semiconductor chip 24 and the package substrate 16 electrically contiguous. In the illustrated example, plural of the bumps 28 are disposed along the vicinity of the outer edge portion of the chip body 26 as viewed along the normal direction (the arrow A1 direction) to the chip body 26.

In the manufacturing method of the present exemplary embodiment, as illustrated in FIG. 1A, the adhesive 30 is coated between the semiconductor chip 24 and the package substrate 16 (on the package substrate 16) at a stage prior to mounting the semiconductor chip 24 on the package substrate 16. A resin adhesive may for example be employed as the adhesive 30.

An example of the bumps 28 is solder bumps, however other bumps may also be employed, such as stud bumps and gold bumps.

In the example illustrated in the drawings, the adhesive 30 is coated on the package substrate 16 at a position between the bumps 28. Then, as illustrated in FIG. 1B, the semiconductor chip 24 is pressed towards and against the package substrate 16, and the adhesive 30 is also pressed out wide by the semiconductor chip 24. The base 18 thereby makes contact with the chip body 26 and the bumps 28 of the semiconductor chip 24 over a wide range, and the semiconductor chip 24 is bonded firmly to the package substrate 16. A portion of the adhesive 30 is squeezed out (sideways in FIG. 1B) further to the outside than the outside edge portion of the chip body 26 of the semiconductor chip 24.

A separating member 32 is interposed between the pressing face 20P of the press member 20 and the semiconductor chip 24. The separating member 32 is made of a material that readily releases from the adhesive 30, and is formed in a film form larger than the outside edge of the semiconductor chip 24. The semiconductor chip 24 is suctioned by the press member 20 though the separating member 32 (with the separating member 32 interposed between the semiconductor chip 24 and the pressing face 20P).

The separating member 32 is employed such that the adhesive 30 that has been squeezed out from the outer edge portion of the chip body 26 does not unintentionally adhere to other members (for example the press member 20). As above, the separating member 32 has high releasing properties to the adhesive 30 and so even if the adhesive 30 adheres it can be readily released. A fluororesin tape formed as a thin film, for example, may be employed for the separating member 32.

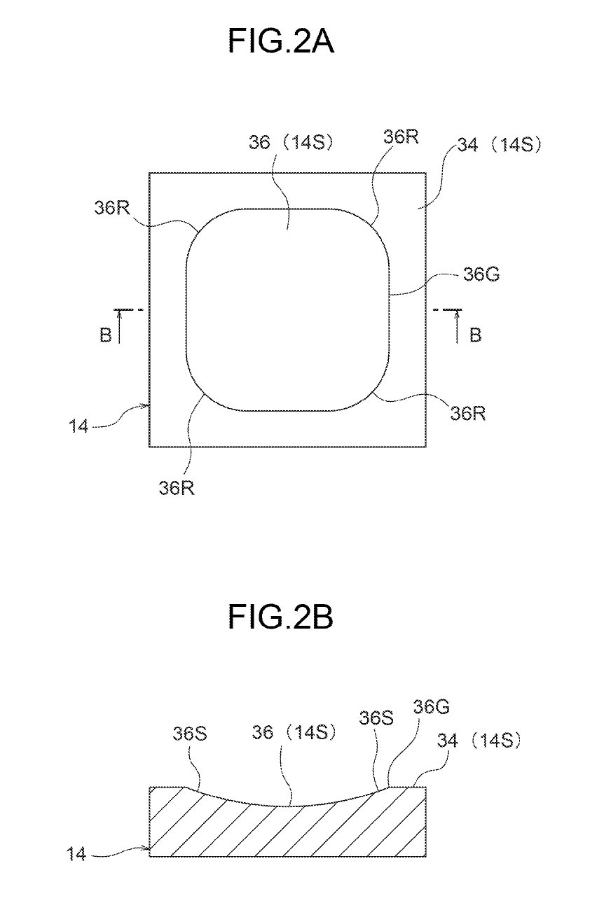

In the present exemplary embodiment, as illustrated in detail in FIG. 2A and FIG. 2B, the support face 14S of the mounting stage 14 includes a frame shaped outer edge flat face 34 positioned at the outer edge portion of the mounting stage 14. A cavity 36 is formed at the center of the support face 14S, formed with a concave shape that curves in from the outer edge flat face 34. Due to being concave and dipping downwards, the cavity 36 has a sloping face 36S that slopes on progression towards the center of the cavity 36.

In the illustrated example the cavity 36 is, as can be seen from FIG. 2B, curved over the whole of the cross-section (however there is no requirement for a constant radius of curvature). Moreover, as can be seen from FIG. 2A, when viewed in plan view an outer periphery 36G is shaped to correspond to the semiconductor chip 24 overall (a substantially square shape), however corner portions are curved with a specific radius of curvature, with rounded portions 36R provided.

The size of the cavity 36 is, as illustrated in FIG. 1A, formed larger than the size of the external profile of the chip body 26 as viewed along a direction normal to the chip body 26 of the semiconductor chip 24 (the arrow A1 direction). Consequently, it is possible to make the bumps 28 and the sloping face 36S face each other across the package substrate 16 when the semiconductor chip 24 is being mounted to the package substrate 16.

When mounting the semiconductor chip 24 to the package substrate 16 and manufacturing a printed circuit board 38, first, as illustrated in FIG. 1A, the package substrate 16 is supported on the support face 14S of the mounting stage 14. Although the cavity 36 is formed in the support face 14S, the package substrate 16 does not warp unintentionally since the base 18 has a specific rigidity. In the present exemplary embodiment the adhesive 30 is coated onto the package substrate 16 in this state.

The semiconductor chip 24 is suctioned by the press member 20 through the separating member 32 so as to face towards the package substrate 16 and be retained at the opposite side of semiconductor chip 24 to the mounting stage 14.

The press member 20 is then driven, and the semiconductor chip 24 pressed towards the package substrate 16. At this stage, the bumps 28 of the semiconductor chip 24 are positionally aligned to face towards the sloping face 36S.

When the semiconductor chip 24 is moved towards the package substrate 16, the semiconductor chip 24 first makes contact with an apex portion of the adhesive 30. The semiconductor chip 24 is then pressed further towards the package substrate 16. At this stage, the separating member 32 softens due to heat, and an evenly distributed load F1 (pressing force) acts on the semiconductor chip 24. As illustrated in FIG. 1B, reaction force acts on the semiconductor chip 24 as the adhesive 30 is being pressed by the semiconductor chip 24 and squeezed out sideways.

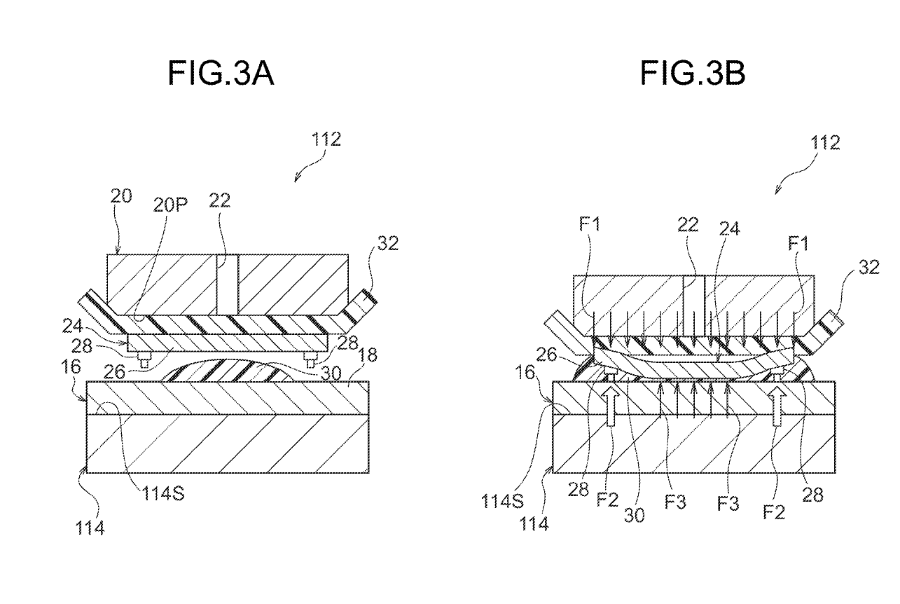

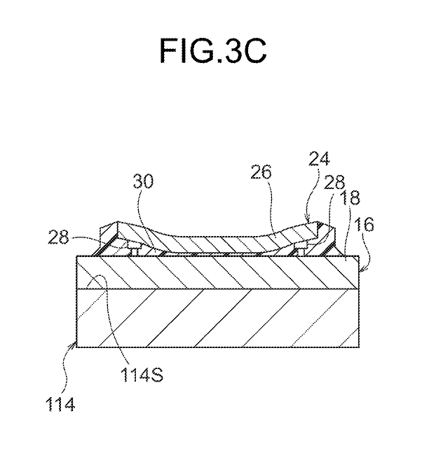

A manufacturing method employing a manufacturing apparatus of a comparative example is illustrated in FIG. 3A to FIG. 3C.

In a manufacturing apparatus 112 of a comparative example, there is no cavity 36 (see FIG. 1A to FIG. 1C and FIG. 2A and FIG. 2B) formed in a support face 114S of a mounting stage 114, and the support face 114S is formed in an entirely flat shape. The mounting stage 114 in the comparative example is of substantially the same configuration as the manufacturing apparatus 12 in the first exemplary embodiment apart from the structure of the mounting stage 114.

Sometimes the semiconductor chip 24 warps when the thickness of the semiconductor chip 24 is thin (rigidity is low). When the manufacturing apparatus 112 of the comparative example is employed, when the semiconductor chip 24 warps, the central portion of the semiconductor chip 24 approaches closer to the package substrate 16 than the outer edge portion of the semiconductor chip 24. Accordingly a greater reaction force F3 from the package substrate 16 acts on the central portion of the semiconductor chip 24 than on the peripheral edge portion of the semiconductor chip 24. The effective reaction force F2 from the package substrate 16 acting on the bumps 28 is accordingly smaller than would otherwise be the case.

The semiconductor chip 24 and the package substrate 16 often have different linear expansion coefficients to each other. Consequently, when deformation of the semiconductor chip 24 as described above is added, the semiconductor chip 24 can deform even further due to the differences in linear expansion coefficients.

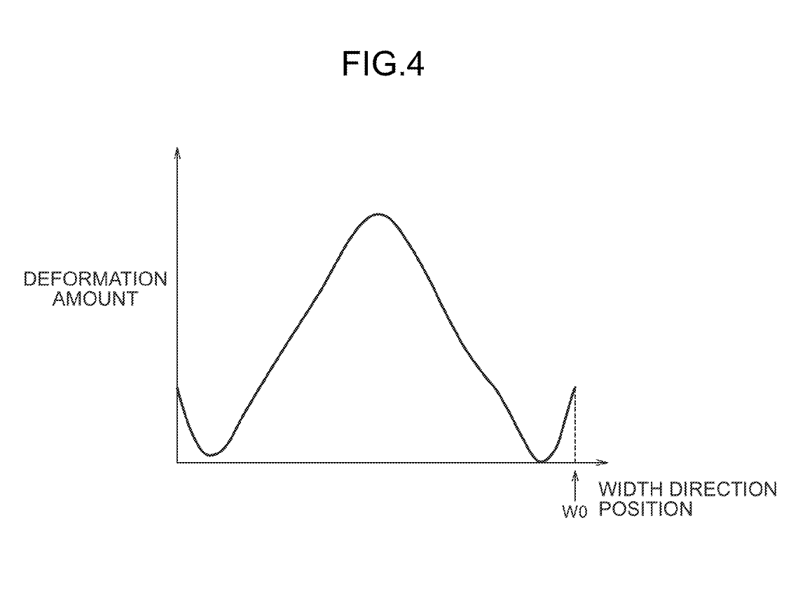

FIG. 4 qualitatively illustrates a relationship between positions in the width direction of the semiconductor chip 24 and the deformation amount. The positions in the width direction here are for example positions from the left hand edge of the semiconductor chip 24 illustrated in FIG. 3B towards the right hand side, and WO illustrates the total width (right hand edge). As illustrated in FIG. 4, in the manufacturing method of the comparative example, there are cases where the deformation amount of the semiconductor chip 24 plots as a substantial W shape (the actual deformation is an inverted W shape).

When the semiconductor chip 24 deforms in this manner, the load (reaction force from the package substrate 16) acting on the bumps 28 decreases yet further since the bumps 28 are provided at peripheral edge portions of the chip body 26.

In comparison thereto, in the present exemplary embodiment, the cavity 36 is formed in the mounting stage 14. Moreover, the sloping face 36S faces towards the bumps 28 across the package substrate 16. Consequently, when the semiconductor chip 24 is pressed against the package substrate 16, as can be seen from FIG. 1B, the package substrate 16 warps to follow the cavity 36. A separation D1 between the semiconductor chip 24 and the package substrate 16 also becomes more uniform over each location than in the structure of the comparative example.

Accordingly, load transmission to the bumps 28 is better than in the structure of the comparative example. In other words it is possible to press the bumps 28 more certainly against the package substrate 16. There are also good contact characteristics of the semiconductor chip 24 to the package substrate 16, resulting in high mounting reliability.

After attaching the semiconductor chip 24 to the package substrate 16, as illustrated in FIG. 1C, the pressing of the press member 20 is released, and the separating member 32 is removed. The adhesive 30 exhibits adhesive force, bonding the semiconductor chip 24 to the package substrate 16. A printed circuit board 48 mounted with the semiconductor chip 24 is accordingly obtained.

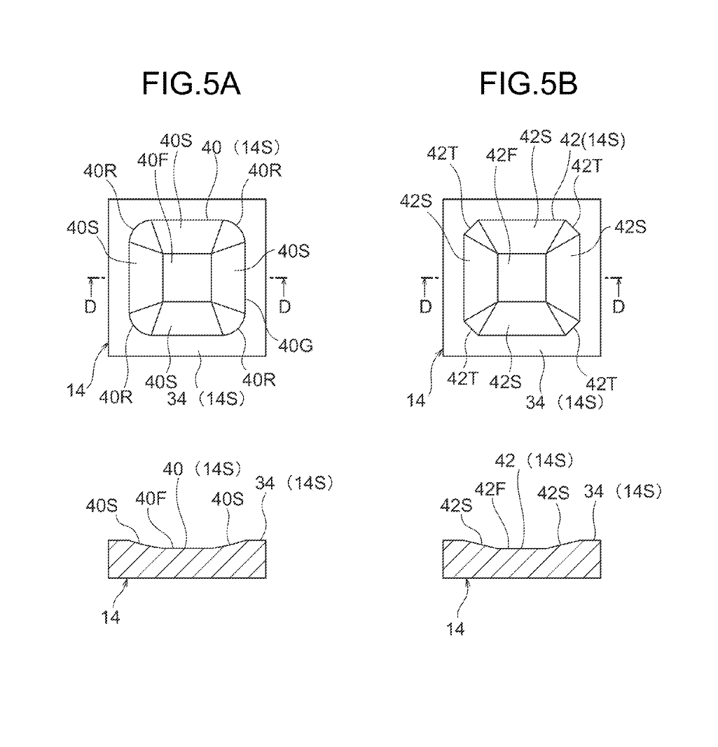

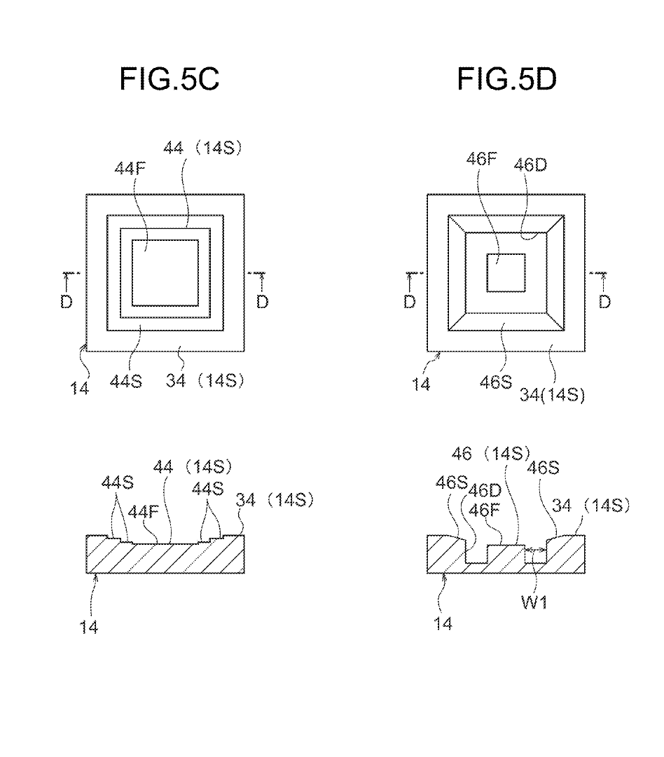

Note that the shape of the cavity is not limited to the entirely curved shape described above, and various other shapes may be employed, such as the examples illustrated in FIG. 5A to FIG. 5D. Note that in FIG. 5A to FIG. 5D, the cross-sections illustrated at the bottom of each figure are cross-sections taken on lines D-D of the plan views illustrated at the top of each figure.

A cavity 40 illustrated in FIG. 5A is formed with a flat central flat face 40F (parallel to the outer edge flat face 34) at the center. The sloping face 40S is formed sloping from the outer edge flat face 34 towards the central flat face 40F between the central flat face 40F and the outer edge flat face 34. In plan view of the cavity 40, an outer periphery 40G of the cavity 40 is formed in a substantially square shape overall, with rounded portions 40R provided at the corner portions, similarly to the cavity 36 illustrated in FIG. 2A.

A cavity 42 illustrated in FIG. 5B is formed at the center with a flat central flat face 42F (parallel to the outer edge flat face 34). The sloping face 42S is formed sloping from the outer edge flat face 34 towards the central flat face 42F between the central flat face 42F and the outer edge flat face 34. This feature is substantially the same as the cavity 40 illustrated in FIG. 5A. However, in plan view of the cavity 42, corner portions of the substantially square shaped outer periphery 36G are beveled with a substantial straight line to provide beveled portions 42T.

The cavities 36, 40, 42 described above are close to the curved shape of the semiconductor chip 24 and the package substrate 16 when the semiconductor chip 24 is being pressed against the package substrate 16. Consequently, they are favorably shaped from the perspective of achieving uniform separation D1 between the semiconductor chip 24 and the package substrate 16 (see FIG. 1B).

In particular, the cavity 36 illustrated in FIG. 2A and FIG. 2B is curved as a whole in cross-section, even more closely approximating to the curved shape of the package substrate 16. Consequently, stress to the package substrate 16 can be suppressed from acting locally when the package substrate 16 is curved.

In contrast thereto, the central flat faces 40F, 42F are formed in the cavities 40, 42. Hence the cavities 40, 42 are accordingly easier to form than the cavity 36 due to being able to employ these central flat faces 40F, 42F as reference positions during forming the cavities 40, 42.

A cavity 44 illustrated in FIG. 5C is formed between a central flat face 44F and the outer edge flat face 34 with plural (two in the illustrated example) step faces 44S from the outer edge flat face 34 approaching the central flat face 44F. The central flat face 44F and the step faces 44S are all faces parallel to the outer edge flat face 34. The cavity 44 does not have a sloping face present from the outer edge flat face 34 towards the central flat face 44F, however a sloping portion is configured that approaches from the outer edge flat face 34 towards the central flat face 44F when the plural step faces 44S are considered as a whole. Note that in plan view the cavity 44 is formed with a square external periphery.

In the cavity 44 the step faces 44S configuring the sloping portion are parallel to the outer edge flat face 34. Hence the cavity 44 is more easily shaped than the cavities 36, 40, 42 since no sloping faces are present, in contrast to the cavities 36, 40, 42.

A cavity 46 illustrated in FIG. 5D is formed with a groove 46D between a central flat face 46F and a sloping face 46S. The groove 46D is formed in a square frame shape surrounding the central flat face 46F in plan view. A width W1 of the groove 46D is set such that when the package substrate 16 is in a curved supported state, the localized indentation caused by the groove 46D is not transmitted to the package substrate 16.

The cavity 46 is more easily shaped than the cavities 40, 42. Namely, with the cavities 40, 42, at the boundary portions between the central flat faces 40F, 42F and the sloping faces 40S, 42S, it is difficult to generate an accurate shape when some of the material generated during processing remains. However, in the cavity 46, the groove 46D acts as a portion into which the above remaining material enters.

The shapes of the cavities illustrated in FIG. 5A to FIG. 5D are merely examples thereof, and the cavity is not limited by these shapes.

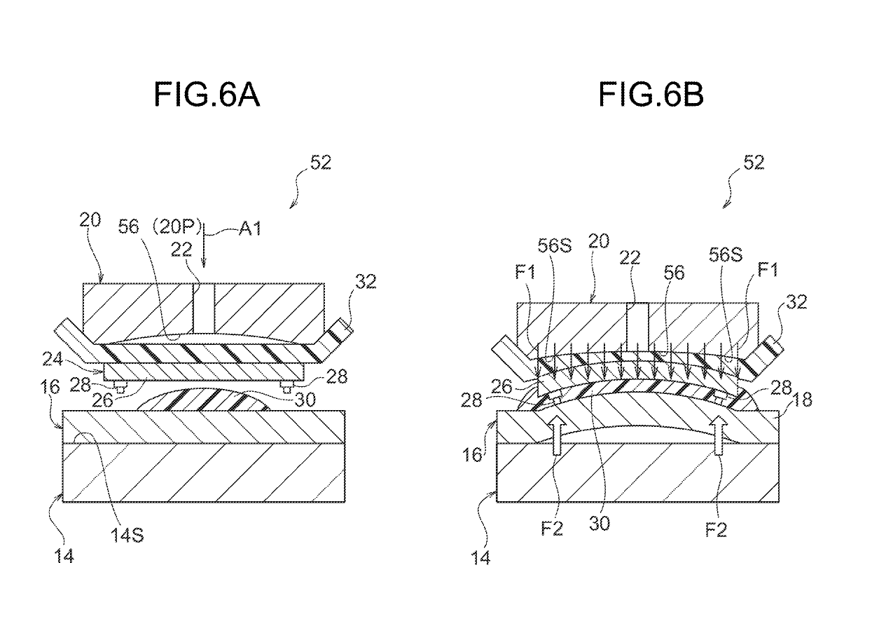

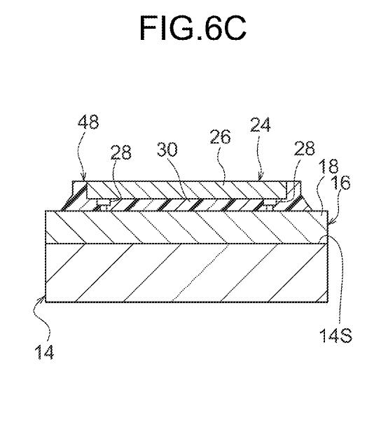

FIG. 6A to FIG. 6C illustrate a manufacturing method of a second exemplary embodiment and part of a printed circuit board manufacturing apparatus applicable to this manufacturing method. Similar configuration elements and members in the second exemplary embodiment to those of the first exemplary embodiment are allocated the same reference numerals and detailed explanation thereof is omitted.

In a manufacturing apparatus 52 of the second exemplary embodiment, an outer edge flat face 54 and a cavity 56 are formed to a pressing face 20P of a press member 20.

The cavity 56 is indented so as to form an overall upwards facing curve, the reverse to the cavity 36 illustrated in FIG. 1A to FIG. 1C and FIG. 2A and FIG. 2B of the first exemplary embodiment, formed with a sloping face 56S. The cavity 56 is formed so as to be larger than the size of the external profile of a chip body 26. It is accordingly possible to make back face portions of bumps 28 of a semiconductor chip 24 face towards the sloping face 56S across the chip body 26 when mounting the semiconductor chip 24.

In the second exemplary embodiment, the cavity 36 (see FIG. 2A and FIG. 2B) of the first exemplary embodiment is not formed in a mounting stage 14, and instead a support face 14S is formed entirely flat.

In the manufacturing method of the second exemplary embodiment, similarly to in the manufacturing method of the first exemplary embodiment, the semiconductor chip 24 is suctioned and held by the press member 20 so as to face towards a package substrate 16 supported on the support face 14S, with a separating member 32 interposed between the semiconductor chip 24 and the press member 20. The press member 20 is driven, and the semiconductor chip 24 is pressed towards the package substrate 16. The semiconductor chip 24 first makes contact with an apex portion of adhesive 30. When the semiconductor chip 24 is pressed further towards the package substrate 16, a load F1 (pressing force) acts on the semiconductor chip 24 through the separating member 32 that has been softened by heat.

When this occurs, the pressing face 20P in the second exemplary embodiment is formed with the cavity 56, and therefore, as illustrated in FIG. 6B, the separating member 32, the semiconductor chip 24, the adhesive 30 and the package substrate 16 curve so as to form a protrusion towards the press member 20 (upwards).

In particular, since the semiconductor chip 24 initially makes contact at the central portions of the adhesive 30 and the package substrate 16, the heat from the press member 20 is transmitted at an early stage. In contrast thereto, heat transmission from the press member 20 to the peripheral edge portions of the adhesive 30 and the package substrate 16 acts later, and heat is also more readily dissipated therefrom to the periphery than from the central portions. The expansion amount of the central portion of the package substrate 16 is accordingly larger, such that the package substrate 16 curves so as to be upwards facing convex.

In the second exemplary embodiment, thus not only the semiconductor chip 24 but also the package substrate 16 curves, and so the separation D1 between the semiconductor chip 24 and the package substrate 16 is made more uniform than in the comparative example (see FIG. 3B), resulting in good load transfer to the bumps 28. It is accordingly possible for the bumps 28 to be more certainly pressed against the package substrate 16. The mounting reliability is high since there are also good contact properties of the semiconductor chip 24 to the package substrate 16.

Similarly to in the first exemplary embodiment, after attaching the semiconductor chip 24 to the package substrate 16, as illustrated in FIG. 6C, pressing from the press member 20 is released and the separating member 32 is removed. A printed circuit board 48 mounted with the semiconductor chip 24 is accordingly obtained.

Note that in the second exemplary embodiment, the shape of the cavity formed in the pressing face 20P is not limited to the shape illustrated in FIG. 6A to FIG. 6C. For example, the various shapes illustrated in FIG. 5A to FIG. 5D may be employed as the shapes that indent upwards.

In the first exemplary embodiment and the second exemplary embodiment, there is no particular limitation to the depth of the deepest portion of the cavity 36. However, a portion of the deformed separating member 32 enters into the cavity 36 when the semiconductor chip 24 is curved. Therefore, when the depth of the deepest portion is set at the thickness of the separating member 32 ±20% then deformation of the separating member 32 can be accommodated with certainty.

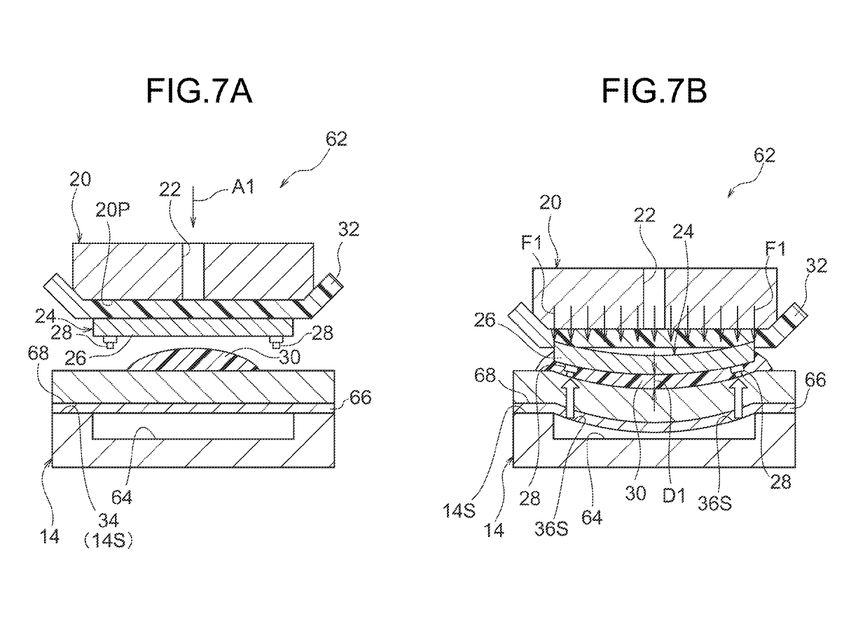

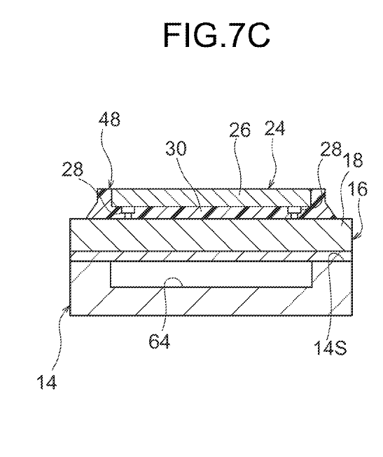

FIG. 7A to FIG. 7C illustrate a manufacturing method of a third exemplary embodiment, and a portion of a printed circuit board manufacturing apparatus applicable to this manufacturing method. Similar configuration elements and members in the third exemplary embodiment to those of the first exemplary embodiment are allocated the same reference numerals and detailed explanation thereof is omitted.

In a manufacturing apparatus 62 of the third exemplary embodiment, a mounting stage 14 is made for example from ceramic set with a linear expansion coefficient that is smaller (substantially no thermal expansion in practice) than that of a package substrate 16.

An indentation 64 is formed in a central portion of a mounting stage 14 (at the inside of an outer edge flat face 34). The indentation 64 in the illustrated example is formed with an indented rectangular shaped support face 14S in cross-section. The indentation 64, as viewed along a normal direction to a chip body 26 (the arrow A1 direction) is formed so as to be larger than the size of the external profile of the chip body 26. The depth of the indentation 64 is, as described later, set to a depth sufficient that a warping member 66 does not make contact when the warping member 66 is in a warped state.

The indentation 64 is covered by the warping member 66. In the present exemplary embodiment, the warping member 66 is formed as a thin film (diaphragm shape) from a metal with a linear expansion coefficient that is about the same as the linear expansion coefficient of the package substrate 16 (for example about 10 to 25 ppm/° C.). The periphery of the warping member 66 is fixed to an outer edge flat face 34. The warping member 66 does not curve in a normal state (for example in a state not pressed from the opposite side of the mounting stage 14), and configures a flat support face 68 on the opposite side to the contact face with the mounting stage 14.

However, when a central portion (a portion corresponding to the indentation 64) of the warping member 66 is pressed from the support face 68 side (the opposite side to that of the mounting stage 14), the warping member 66 curves so as to enter into the indentation 64. In particular, as illustrated in FIG. 7B, in the manufacturing process a sloping face 36S appears at the portion facing towards bumps 28 of a semiconductor chip 24 across the package substrate 16.

In the manufacturing method of the third exemplary embodiment, the package substrate 16 is supported on the mounting stage 14 that is a support member through the warping member 66 (in contact with the support face 68).

Then, similarly to in the manufacturing method of the first exemplary embodiment, the semiconductor chip 24 is suctioned and held by the press member 20 through a separating member 32 so as to face towards the package substrate 16 being supported at the support face 68. The press member 20 is then driven, and the semiconductor chip 24 is pressed towards and against the package substrate 16. The semiconductor chip 24 first makes contact with an apex portion of adhesive 30. When the semiconductor chip 24 is then pressed further against the package substrate 16, an evenly distributed load F1 (pressing force) acts on the semiconductor chip 24 through the separating member 32 that has been softened by heat. The adhesive 30 pressed by the semiconductor chip 24 is pressed towards the mounting stage 14 whilst being squeezed out sideways.

In the third exemplary embodiment, the indentation 64 of the mounting stage 14 is covered by the warping member 66. Consequently, when the warping member 66 is pressed in this manner, as illustrated in FIG. 7B, the central portion of the warping member 66 curves so as to enter into the indentation 64. A sloping face 68S then appears on the support face 68 of the warping member 66 at least at the portion making contact with the bumps 28. Note that in the illustrated example the warping member 66 is curved over substantially the entire portion covering the indentation 64.

In the third exemplary embodiment, the separation D1 between the semiconductor chip 24 and the package substrate 16 is made more uniform than in the structure of the comparative example (see FIG. 3B) by the warping member 66 curving in this manner, resulting in favorable load transfer to the bumps 28. It is accordingly possible to press the bumps 28 more certainly against the package substrate 16. There are also good contact characteristics of the semiconductor chip 24 to the package substrate 16, resulting in high mounting reliability.

Similarly to in the first exemplary embodiment and the second exemplary embodiment, after attaching the semiconductor chip 24 to the package substrate 16, as illustrated in FIG. 7C, pressing from the press member 20 is released, and the separating member 32 is removed. A printed circuit board 48 is accordingly obtained mounted with the semiconductor chip 24.

In particular, in the above example the linear expansion coefficient of the warping member 66 is similar to the linear expansion coefficient of the package substrate 16. Accordingly, when there is an uneven internal temperature distribution for the package substrate 16, deformation follows the unevenness in temperature, and the warping member 66 also warps. Consequently, the separation D1 between the semiconductor chip 24 and the package substrate 16 is made more uniform than in a different configuration in which the linear expansion coefficient of the warping member 66 is differs greatly to the linear expansion coefficient of the package substrate 16. The favorable effect on load transfer to the bumps 28 is accordingly enhanced.

Note that in the third exemplary embodiment, there are no particular limitations to the thickness of the warping member 66 as long as the desired warp shape can be realized when pressed by the adhesive 30 as described above. From this perspective, the thickness of the warping member 66 is preferably for example 0.2 mm or thinner. However, since the rigidity of the warping member 66 is lowered when the thickness is made too thin, the thickness of the warping member 66 is preferably for example 0.05 mm or greater from the perspective of obtaining the appropriate rigidity.

The respective manufacturing methods of all of the exemplary embodiments can be favorably applied to manufacture of the printed circuit board 38 when the semiconductor chip 24 is thin. Namely, when the semiconductor chip 24 is thick (for example a thickness of about 100 μm) then since the rigidity is high, warping such as illustrated in FIG. 3B does not readily occur in the semiconductor chip 24. Sufficient pressing load can accordingly be transmitted to the bumps 28.

In contrast thereto, when the semiconductor chip 24 is thin (for example a thickness of about 50 μm) then since the rigidity is low, warping such as illustrated in FIG. 3B readily occurs. In particular, low height (low profiling) is demanded in a printed circuit board 38 with the semiconductor chip 24 flip-chip mounted thereto. The thickness of the semiconductor chip 24 is therefore sometimes made thin. When such thin semiconductor chips are employed, the embodiments discussed herein enable the separation D1 between the semiconductor chip 24 and the package substrate 16 to be made more uniform than in the comparative structure, and enable good load transfer to the bumps 28 to be achieved.

Although embodiments of the technology disclosed herein have been explained above, the technology disclosed herein is not limited by the above, and it should be understood that it is possible to implement various modifications other than described above without departing from the spirit and scope of the technology disclosed herein.

According to the printed circuit board manufacturing method disclosed herein, a more uniform load pressing a semiconductor chip against a substrate is possible during mounting of a semiconductor chip to a substrate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

All cited documents, patent applications and technical standards mentioned in the present specification are incorporated by reference in the present specification to the same extent as if the individual cited documents, patent applications and technical standards were specifically and individually incorporated by reference in the present specification.

What is claimed is:

1. A printed circuit board manufacturing method comprising:
supporting a substrate on a support member;
disposing a semiconductor chip on an opposite side of the substrate from the support member and pressing the semiconductor chip against the substrate with a pressing member;
employing as the support member a member formed with a cavity larger than an external profile of the semiconductor chip to be mounted to the substrate and formed, at at least a portion of a bottom face of the cavity, with a sloping portion towards a center of the cavity, and causing a bump of the semiconductor chip to face towards the sloping portion when the semiconductor chip is pressed towards the substrate; and
bonding the semiconductor chip to the substrate with an adhesive interposed between the substrate and the semiconductor chip.

2. The printed circuit board manufacturing method of claim 1, wherein
the cavity employed includes a sloping face that slopes towards the center of the cavity and configures the sloping portion.

3. The printed circuit board manufacturing method of claim 2, wherein
the cavity employed is formed with an overall curved profile as viewed in a cross-section of the support member along a mounting direction of the semiconductor chip.

4. The printed circuit board manufacturing method of claim 2, wherein
the cavity employed includes a central flat face at the center of the cavity as viewed in a cross-section of the support member along a mounting direction of the semiconductor chip and the sloping face positioned at both sides of the central flat face.

5. The printed circuit board manufacturing method of claim 1, wherein
the cavity employed includes a plurality of step faces that are formed in step shapes towards the center of the cavity and that configure the sloping portion.

6. The printed circuit board manufacturing method of claim 5, wherein
the cavity employed includes a central flat face at the center of the cavity as viewed in a cross-section of the support member along a mounting direction of the semiconductor chip and the plurality of step faces positioned at both sides of the central flat face.

7. A printed circuit board manufacturing method comprising:
supporting a substrate on a support member;
disposing a semiconductor chip on an opposite side of the substrate from the support member and pressing the semiconductor chip against the substrate with a pressing member;
employing as the pressing member a member formed with a cavity larger than an external profile of the semiconductor chip to be mounted to the substrate and formed, at at least a portion of a bottom face of the cavity, with a sloping portion towards a center of the cavity, and causing a bump back face portion of the semiconductor chip to face towards the sloping portion when the semiconductor chip is pressed towards the substrate; and
bonding the semiconductor chip to the substrate with an adhesive interposed between the substrate and the semiconductor chip.

8. The printed circuit board manufacturing method of claim 7, wherein
the cavity employed includes a sloping face that slopes towards the center of the cavity and configures the sloping portion.

9. The printed circuit board manufacturing method of claim 8, wherein
the cavity employed is formed with an overall curved profile as viewed in a cross-section of the pressing member along a mounting direction of the semiconductor chip.

10. The printed circuit board manufacturing method of claim 8, wherein
the cavity employed includes a central flat face at the center of the cavity as viewed in a cross-section of the pressing member along a mounting direction of the semiconductor chip and the sloping face positioned at both sides of the central flat face.

11. The printed circuit board manufacturing method of claim 7, wherein
the cavity employed includes a plurality of step faces that are formed in step shapes towards the center of the cavity and that configure the sloping portion.

12. The printed circuit board manufacturing method of claim 11, wherein
the cavity employed includes a central flat face at the center of the cavity as viewed in a cross-section of the pressing member along a mounting direction of the semiconductor chip and the plurality of step faces positioned at both sides of the central flat face.

13. A printed circuit board manufacturing method comprising:
supporting a substrate on a support member;
disposing a semiconductor chip on an opposite side of the substrate from the support member and pressing the semiconductor chip against the substrate with a pressing member;
employing as the support member a member formed with an indentation larger than an external profile of the semiconductor chip to be mounted to the substrate and disposed with a warping member capable of warping deformation so as to cover the indentation, wherein a bump of the semiconductor chip causes at least a bump contact portion of the warping member to slope towards a center of the indentation when the semiconductor chip is pressed towards the substrate; and
bonding the semiconductor chip to the substrate with an adhesive interposed between the substrate and the semiconductor chip.
